(19) United States
(12) Patent Application Publication
(10) Pub. No.: US 2024/0297101 A1
(43) Pub. Date: Sep. 5, 2024

(54) PACKAGING METHOD

(71) Applicant: Richtek Technology Corporation, Hsinchu (TW)

(72) Inventors: Yu-Lin Yang, Penghu (TW); Ming-Chih Hsu, Taichung (TW); Chun-Hao Chang, Hsinchu (TW)

(21) Appl. No.: 18/308,665

(22) Filed: Apr. 27, 2023

(30) Foreign Application Priority Data
Mar. 2, 2023 (TW) 112107609

(51) Int. Cl. H01L 23/495; H01L 21/48; H01L 21/56; H01L 23/31

(52) U.S. Cl. CPC H01L 23/49534; H01L 21/4828; H01L 21/4842; H01L 21/565; H01L 23/3107; H01L 23/49541

(57) ABSTRACT

A packaging method, includes: providing a continuous multi-package structure, which includes a lead frame and a molding layer formed on the lead frame, wherein the lead frame includes a plurality of recesses formed on a bottom surface on a side of the lead frame opposite to the molding layer; forming a coating layer on the bottom surface, to cover the bottom surface and the recesses on the bottom surface; and mechanically cutting the continuous multi-package structure through the recesses, to separately form a plurality of packaging units, wherein in each of the packaging units, an exposed portion of the lead frame exposed in the recesses includes a step shape.

### CROSS REFERENCE

The present invention claims priority to TW 112107609 filed on Mar. 2, 2023.

### BACKGROUND OF THE INVENTION

### Field of Invention

The present invention relates to a packaging method, in particular a packaging method for producing package units in simple steps to have stable quality.

### Description of Related Art

In recent years, quad flat no lead (QFN) package having a smaller package volume has been one of the package mainstream technologies, wherein although the package is small, it can afford a large number of welding pads for electrical signal transmission. Further, such leadless package has excellent heat dissipation performance. For the above reasons, the quad flat no lead package technology is widely applied in various package configurations.

In the development of quad flat no lead structures, the solder coverage on the side walls is typically between 50% and 90%. However, in industries requiring high soldering quality, such as in the automotive industry, poor soldering quality can cause significant production loss due to unstable assembly quality. A technology of forming wettable flanks on the step shape on the exposed side walls of the pad is proposed, which can increase the wettable area on the pad to improve the bonding contact strength for electrical connection to the printed circuit board.

FIGS. 1A to 1I illustrate conventional manufacturing steps for the wettable flank package. In the drawings, for better illustration, the lead frame and the molder are shown in a simplified form without showing the complete structure and components (such as die and lead wires) in detail. FIG. 1A illustrates a lead frame 20; FIG. 1B illustrates the formation of a molding layer 40 on the lead frame 20; FIG. 1C illustrates the formation of a pre-plating layer PCO on a bottom surface 26 of the lead frame 20; FIGS. 1D and 1E illustrate that a pre-cutting tool TP digs a recess 22 into the lead frame 20 and the pre-plating layer PCO; FIG. 1F illustrates the removal of the pre-plating layer PCO by de-burr and de-plating processes, to clean the recesses 22; FIG. 1G illustrates the formation of a coating layer 60 on the bottom surface 26 of the lead frame 20; FIG. 1H illustrates that a mechanical cutting tool TL divides the lead frame 20 and the molding layer 40 to separately form plural packaging units PAU, wherein the arrow shows the cutting direction of the mechanical cutting tool TL; FIG. 1I illustrates that at the peripheral sides of each packaging unit PAU, the exposed portion of the lead frame 20 (corresponding to the edge of the recess 22) has a step shape side wall LW. The step shape side wall LW is formed by twice mechanical machining, which are digging the recess 22 and dividing the package structure.

In this prior art manufacturing process, before the first mechanical machining process, the bottom surface 26 of the lead frame 20 is protected by the pre-plating layer PCO, to avoid unnecessary damage such as layer peeling during the de-burr process. Mechanical machining may have deviations on the machining surface and may have machining chatter, which are particularly obvious during the recess machining process. The size and flatness of the recess 22 may become unstable and even include warpage. During forming the recess 22, the machining process may generate residues which are particles of the lead frame, the molding layer or the pre-plating layer (PCO). Therefore, de-burr and de-plating processes are required to clean the bottom surface 26 for the following processes to cur the package structure into plural packaging units. The de-burr and de-plating processes are very complicated and may cause unwanted damage on the welding pad. Further, the pad unevenness may be even more serious due to electroplating on a poorly flattened pad.

The aforementioned steps are complicated and costly in terms of processing time, equipment and associated materials. Further, the two material removal processes increase the risk of damaging the package structure.

To address the shortcomings of the prior art technology, the present invention provides a packaging method, especially applicable to the wettable flank quad flat no lead package, to significantly reduce the production defect rate.

### SUMMARY OF THE INVENTION

In one perspective, the present invention provides a packaging method, comprising: providing a continuous multi-package structure, which includes a lead frame and a molding layer formed on the lead frame, wherein the lead frame includes a plurality of recesses formed on a bottom surface on a side of the lead frame opposite to the molding layer; forming a coating layer on the bottom surface, to cover the bottom surface and the recesses on the bottom surface; and mechanically cutting the continuous multi-package structure through the recesses, to separately form a plurality of packaging units, wherein in each of the packaging units, an exposed portion of the lead frame exposed in the recesses includes a step shape.

In one embodiment, the molding layer substantially includes a molding material formed on the lead frame, and the packaging method further comprises a laser removal step to remove the molding material left in the recesses.

In one embodiment, the lead frame includes a plurality of welding pads in the exposed portion, and the welding pads respectively include a plurality of step shape side walls.

In one embodiment, the pitch between the welding pads has a minimum value of 0.2 millimeter.

In one embodiment, the pitch between the welding pads has a minimum value of 0.3 millimeter.

In one embodiment, the packaging method further comprises: forming the recesses on the lead frame by an etching step.

In one embodiment, the packaging method does not include removing mechanical machining residues.

In one embodiment, the package structure of the package unit can be applied to a package of quad flat no lead (QFN), dual flat no lead (DFN), or small outline no lead (SON).

In one embodiment, the recesses correspond to separation boundaries between the packaging units in the continuous multi-package structure.

In one perspective, the invention provides a packaging method, which comprises: providing a lead frame including a bottom surface, the bottom surface including a plurality of recesses which are formed on the lead frame by an etching step; providing a molding material to form a molding layer on the lead frame, the lead frame and the molding layer forming a continuous multi-package structure, wherein the molding layer is formed on a side of the lead frame opposite to the bottom surface; removing the molding material left in the recesses by a laser removal step; forming a coating layer on the bottom surface, to cover the bottom surface and the recesses on the bottom surface; and mechanically cutting the continuous multi-package structure through the recesses, to separately form a plurality of packaging units, wherein in each of the packaging units, an exposed portion of the lead frame exposed in the recesses includes welding pads having a step shape.

The objectives, technical details, features, and effects of the present invention will be better understood with regard to the detailed description of the embodiments below, with reference to the attached drawings.

### BRIEF DESCRIPTION OF THE DRAWINGS

FIGS. 1A to 1I show steps in the prior packaging method of wettable flank.

FIGS. 2A to 2E show schematic diagrams of the steps in the packaging method according to one embodiment of the present invention.

FIG. 3 shows a schematic view of a quad flat no lead package structure with wettable flanks according to one embodiment of the present invention.

FIG. 4 shows a 3-dimensional view of a wettable flank quad flat no lead package structure according to one embodiment of the present invention.

### DESCRIPTION OF THE PREFERRED EMBODIMENTS

The drawings as referred to throughout the description of the present invention are for illustration only, to show the interrelations between the steps, the components or the units, but not drawn according to actual scale of sizes.

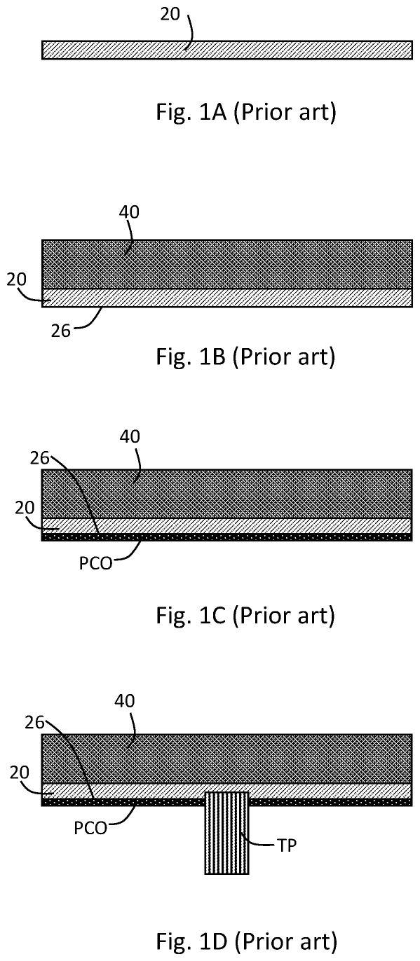

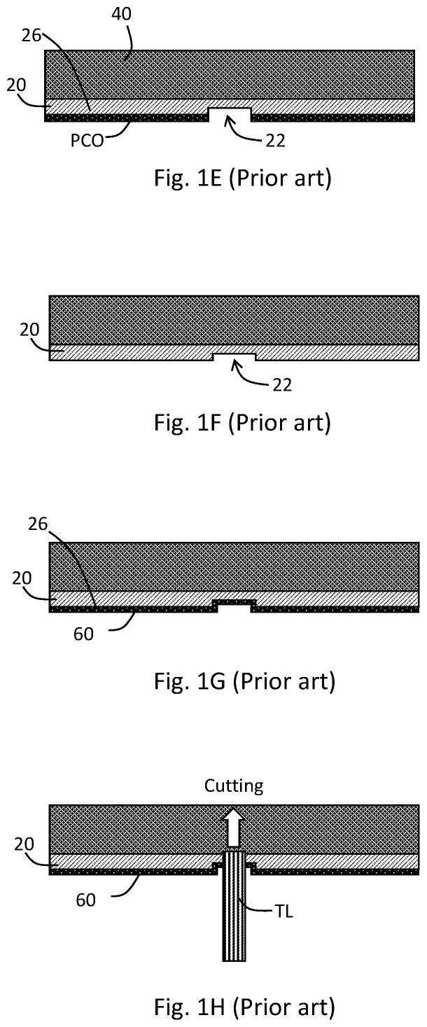

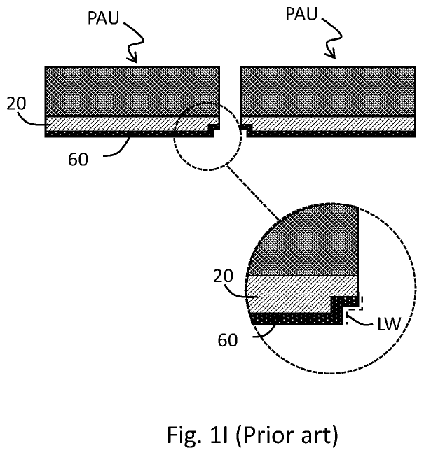

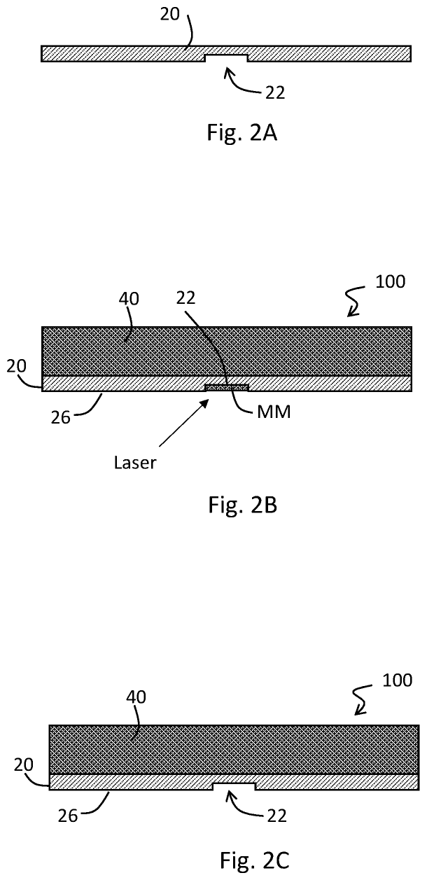

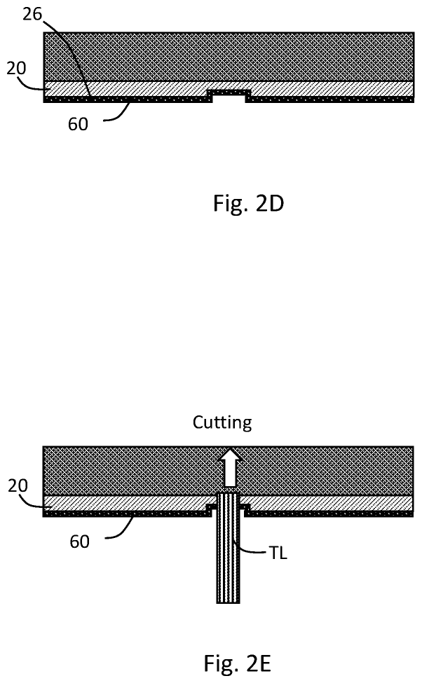

FIGS. 2A to 2E show the steps in a packaging method of the invention. In one embodiment, the packaging method starts from FIG. 2C: providing a continuous multi-package structure 100, wherein the continuous multi-package structure 100 includes a lead frame 20 and a molding layer 40 formed on the lead frame 20. The lead frame 20 includes plural recesses 22 (the drawing shows a part of the lead frame 20 with one of the recesses 22 formed on the lead frame 20; the whole lead frame 20 can include plural recesses 22). The recess 22 is formed on a bottom surface 26 on a side of the lead frame 20 opposite to the molding layer 40 (the bottom surface 26 is shown as the underside surface of the lead frame 20, wherein the drawing shows only a part of the bottom surface 26). Next, a coating layer 60 is formed on the bottom surface 26 (FIG. 2D), to cover the bottom surface 26 and the recess 22 of the bottom surface 26. Next, a mechanical cutting tool TL mechanically cuts (FIG. 2E) the continuous multi-package structure 100 through the recess 22 to separately form plural package units PAU (referring to FIG. 1I). In each package unit PAU, in the exposed portion of the recess 22 left after cutting, the lead frame 20 and the coating layer 60 form a step shape. When the package unit PAU is mounted onto a circuit board PCB, the coating layer 60 provides a solder bonding function between the circuit board PCB and the package unit PAU. In comparison with the prior art technology, the present invention is much simpler in regard of the recess forming process and in regard of the coating and mechanically cutting processes (wherein there is only one mechanical process), and the present invention significantly improves the production instability problem in the prior art.

In one embodiment, the packaging structure of the invention can be a quad flat no lead package structure with wettable flanks, for applications in industries with critical PCB reliability requirements, for example in industries such as power machine, movable sports equipment, devices with oscillating movements, automobiles etc. The quad flat no lead package structure with wettable flanks according to the present invention can meet these high reliability requirements.

The packaging method according to the present invention, needs fewer steps, less processing time, less equipment, lower material cost than the prior art technology. Further, the product quality of the present invention is stable.

This invention focuses on packaging method, so the specification and the drawings only focus on the lead frame, the molding layer and the coating layer, without showing details of the other structural components (e.g., die, lead wire, etc.).

In one embodiment, the molding layer 40 substantially includes a molding material. In one embodiment, after forming the molding layer 40 on the lead frame 20, the packaging method further comprises a laser removal step to remove the molding material MM left in the recess 22 (FIGS. 2B and 2C). After this step, the recess 22 is exposed on the bottom surface 26 of the lead frame 20 and is prepared for the next manufacturing step on the bottom surface 26: forming a coating layer 60 on the bottom surface 26 (FIG. 2D). The process of forming the recess 22 by the present invention is simpler and more stable over the prior art technology which requires pre-deposition, mechanical processing, and complicated processes such as de-burr and de-plating processes. In the present invention, the laser removal step vaporizes and removes the molding material left inside the recess 22. By controlling the laser energy and operational parameters, only the molding material is removed without removing or damaging the metal portion of the lead frame 20, so that the residues are cleaned and the lead frame 20 is intact.

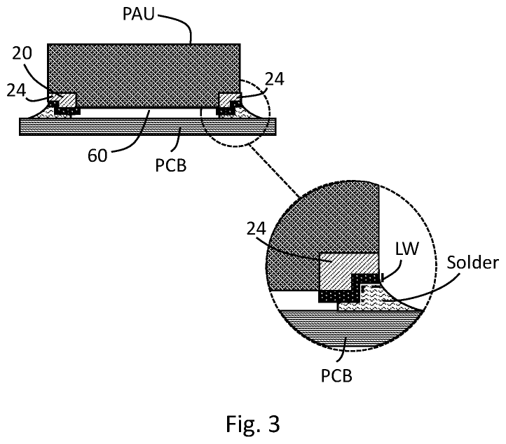

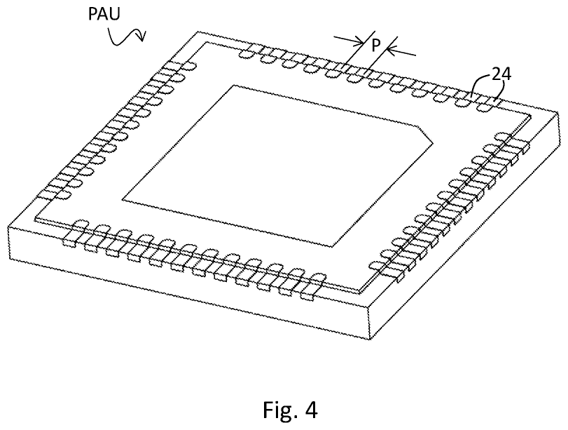

Referring to FIGS. 3 and 4, in one embodiment, the lead frame 20 includes plural welding pads 24 in the exposed portion of the quad flat no lead package structure with the wettable flanks, wherein each welding pad 24 has a step shape side walls LW. The coating layer 60 on the step shape side wall LW provides the solder bonding function. The step shape side wall LW can provide a larger solder bonding area and leaves a gap for filling more solder material, which can significantly reduce defects such as solder voids, to have excellent solder bonding reliability.

Referring to FIG. 4, in one embodiment, the pitch P between the welding pads 24 has a minimum value, which is 0.3 mm (millimeter) In one embodiment, and can be as short as 0.2 mm if necessary. That is, the minimum value is preferably 0.3 mm, and even more preferably 0.2 mm. In the prior art, the pitch between the welding pads 24 is generally 0.4 mm, 0.45 mm or 0.5 mm, which cannot be shortened due to the limitations of the prior art recess digging method and the associated electrical property constraints. Under the same package scale, the pitch of the present invention is much shorter than the pitch in the prior art, so that the package unit PAU of the present invention can include more welding pads 24 than the prior art package structure.

In one embodiment, the packaging method further comprises: forming a recess 22 in the lead frame 20 by etching (FIG. 2A). In different embodiments, the recess 22 can be formed by various etching methods, such as wet etching. In addition, the size of the recess 22 may be designed to be proportional to the thickness of the lead frame 20. In one embodiment, the depth of the recess 22 is half the thickness of the lead frame 20. In other embodiments, different ratios between the size of the recess 22 and the thickness of the lead frame 20 can be designed.

In one embodiment, the process of forming the recess 22 does not include the steps of removing mechanical machining residues and de-plating. In another perspective, in the present invention from the step of the provision of the continuous multi-package structure 100 through the step of separation into plural packaging units PAU, the packaging method of the present invention does not require at least one of the de-plating step and the removal step of mechanical machining residues.

In one embodiment, the package structure formed by the method of the invention can be quad flat no lead (QFN) package, dual-flat no lead (DFN) package, or small outline no lead (SON) package.

In one embodiment, the recesses 22 correspond to separation boundaries (cutting lines) between the package units PAU in the continuous multi-package structure 100. Thus, the step shape side wall LW is formed on the peripheral side of the bottom of each of the packaging units PAU.

If we define the warpage status as the deviation of the welding pad 24 or the distortion of the welding pad 24, which is expressed by a ratio of the depth of the recess 22 or a ratio of thickness of the lead frame 20, the present invention has a lower warpage status than the prior art, because the present invention does not require the mechanical machining process for forming the recess 22, the removal step of the mechanical machining residues and the de-plating step; thus, fewer machining steps can reduce the warpage status.

In one perspective, the present invention provides a packaging method, which comprises: providing a lead frame 20, the lead frame 20 including plural recesses 22 formed on the lead frame 20 by an etching step (FIG. 2A); providing a molding material, to form a molding layer 40 on the lead frame 20, so that the lead frame 20 and the molding layer 40 form a continuous multi-package structure 100, wherein the recesses 22 are formed on a bottom surface 26 on a side of the lead frame 20 opposite to the molding layer 40 (FIG. 2B); removing the molding material left in the recesses 22 by a laser removal step (FIGS. 2B to 2C); on the bottom surface 26, forming a coating layer 60 to cover the bottom surface 26 and the recesses 22 (FIG. 2D); and mechanically cutting the continuous multi-package structure 100 through the recess 22 (FIG. 2E), to separately form plural packaging units PAU (referring to FIG. 1I). After mechanically cutting, in each of the package units PAU, the exposed portion of each recess 22 left after cutting serves as a welding pad 24, and each welding pad 24 includes a step shaped side wall LW (FIG. 3).

The present invention has been described in considerable detail with reference to certain preferred embodiments thereof. It should be understood that the description is for illustrative purpose, not for limiting the scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, the number of chip dies in the package unit, the ratio between the lead frame and the molding layer, or the number or configuration of the welding pads, can be different from the drawings. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A packaging method, comprising:
providing a continuous multi-package structure, which includes a lead frame and a molding layer formed on the lead frame, wherein the lead frame includes a plurality of recesses formed on a bottom surface on a side of the lead frame opposite to the molding layer;
forming a coating layer on the bottom surface, to cover the bottom surface and the recesses on the bottom surface; and
mechanically cutting the continuous multi-package structure through the recesses, to separately form a plurality of packaging units, wherein in each of the packaging units, an exposed portion of the lead frame exposed in the recesses includes a step shape.

2. The packaging method according to claim 1, wherein the molding layer substantially includes a molding material formed on the lead frame, and the packaging method further comprising a laser removal step to remove the molding material left in the recesses.

3. The packaging method according to claim 1, wherein the lead frame includes a plurality of welding pads in the exposed portion, and the welding pads respectively include a plurality of step shape side walls.

4. The packaging method according to claim 3, wherein a pitch between the welding pads has a minimum value of 0.2 millimeter.

5. The packaging method according to claim 3, wherein a pitch between the welding pads includes a minimum value of 0.3 millimeter.

6. The packaging method according to claim 1, further comprising: forming the recesses on the lead frame by an etching step.

7. The packaging method according to claim 1, wherein the packaging method does not include removing mechanical machining residues.

8. The packaging method according to claim 1, wherein the package structure of the package unit is applied to a package of quad flat no lead (QFN), dual flat no lead (DFN), or small outline no lead (SON).

9. The packaging method according to claim 1, wherein the recesses correspond to separation boundaries between the package units.

10. A packaging method, comprising:
providing a lead frame including a bottom surface, the bottom surface including a plurality of recesses which are formed on the lead frame by an etching step;
providing a molding material to form a molding layer on the lead frame, the lead frame and the molding layer forming a continuous multi-package structure, wherein the molding layer is formed on a side of the lead frame opposite to the bottom surface;
removing the molding material left in the recesses by a laser removal step;
forming a coating layer on the bottom surface, to cover the bottom surface and the recesses on the bottom surface; and
mechanically cutting the continuous multi-package structure through the recesses, to separately form a plurality of packaging units, wherein in each of the packaging units, an exposed portion of the lead frame exposed in the recesses includes welding pads having a step shape.

11. The packaging method according to claim 10, wherein the packaging method does not include removing mechanical machining residues.

12. The packaging method according to claim 10, wherein the package structure of the package unit is applied to a package of quad flat no lead (QFN), dual flat no lead (DFN), or small outline no lead (SON).
